(19) United States
(12) Patent Application Publication
(10) Pub. No.: US 2009/0309597 A1
(43) Pub. Date: Dec. 17, 2009

(54) Superparamagnetic Nanoparticles Based on Iron Oxides with Modified Surface, Method of Their Preparation and Application

(76) Inventors: Daniel Horák, Praha (CZ); Eva Syková, Praha (CZ); Michal Babic, Kromeriz (CZ); Pavla Jendelová, Stredokluky (CZ); Milan Hájek, Praha (CZ)

Correspondence Address: NOTARO & MICHALOS P.C., 100 DUTCH HILL ROAD, SUITE 110, ORANGEBURG, NY, 10962-2100, US

(21) Appl. No.: 12/280,440

(22) PCT Filed: Feb. 23, 2007
(86) PCT No.: PCT/CZ07/00012

§ 371 Date: Oct. 20, 2008

(30) Foreign Application Priority Data
Feb. 24, 2006 (CZ) PV 2006-120

(51) Int. Cl. G01R 33/44; B01J 19/10; H01F 1/26; H01F 1/00; G01R 1/06

(52) U.S. Cl. 324/318; 204/157.42; 252/62.54; 252/62.56; 977/960; 324/149

(57) ABSTRACT

The subject of the invention is superparamagnetic nanoparticle probes based on iron oxides, to advantage magnetite or maghemite, with modified surface, coated with mono-, di- or polysaccharides from the group including D-arabinose, D-glucose, D-galactose, D-mannose, lactose, maltose, dextrans and dextrins, or with amino acids or poly(amino acid)s from the group including alanine, glycine, glutamine, asparagine, histidine, arginine, L-lysine, aspartic and glutamic acid or with synthetic polymers based on (meth)acrylic acid and their derivatives selected from the group containing poly(N,N-dimethylacrylamide), poly(N,N-dimethylmethacrylamide), poly(N,N-diethylacrylamide), poly(N,N-diethylmethacrylamide), poly(N-isopropylacrylamide), poly(N-isopropylmethacrylamide), which form a colloid consisting of particles with narrow distribution with polydispersity index smaller than 1.3, the average size of which amounts to 0.5-30 nm, to advantage 1-10 nm, the iron content is 70-99.9 wt. %, to advantage 90 wt. %, the modification agent content 0.1-30 wt. %, to advantage 10 wt. %.

The particles of size smaller than 2 nm with polydispersity index smaller than 1.1 can be obtained by a modified method of preparation.

Superparamagnetic nanoparticle probes according to the invention are prepared by pre-precipitation of colloidal Fe(OH)₃ by the treatment of aqueous 0.1-0.2M solution of Fe(III) salt, to advantage FeCl₃, with less than an equimolar amount of NH₄OH, at 21° C., under sonication, to which a solution of a Fe(II) salt, to advantage FeCl₂, is added in the mole ratio Fe(III)/Fe(II)=2 under sonication and the mixture is poured into five- to tenfold, to advantage eightfold, molar excess of 0.5M NH₄OH. The mixture is left aging for 0-30 min, to advantage 15 min, and then the precipitate is repeatedly, to advantage 7-10 times, magnetically separated and washed with deionized water. Then 1-3 fold amount, to advantage 1.5 fold amount, relative to the amount of magnetite, of 0.1 M aqueous solution of sodium citrate is added and then, dropwise, 1-3 fold amount, to advantage 1.5 fold amount, relative to the amount of magnetite, of 0.7 M aqueous solution of sodium hypochlorite. The precipitate is repeatedly, to advantage 7-10 times, washed with deionized water under the formation of colloidal maghemite to which, after dilution, is added dropwise, to advantage under 5-min sonication, an aqueous solution of a modification agent, in the weight ratio modification agent/iron oxide=0.1-10, to advantage 0.2 for amino acids and poly(amino acid)s and 5 for saccharides.

The particles smaller than 2 nm with polydispersity index smaller than 1.1 are prepared by mixing at 21° C. 1 volume part of 10-60 wt. %, to advantage 50 wt. %, of an aqueous solution of a saccharide, disaccharide or polysaccharide, such as D-arabinose, D-glucose, D-galactose, D-mannose, lactose, maltose, dextran and dextrins, and 1 volume part of aqueous solution of a Fe(II) and Fe(III) salt, to advantage FeCl₂ and FeCl₃, where the molar ratio Fe(III)/Fe(II)=2. A 5-15%, to advantage 7.5%, solution of NH₄OH is added until pH 12 is attained and the mixture is heated at 60° C. for 15 min. The mixture is then sonicated at 350 W for 5 min and then washed for 24 h by dialysis in water using a membrane with molecular weight cut-off 14,000 until pH 7 is reached. The volume of solution is reduced by evaporation so that the final dry matter content is 50-100 mg/ml, to advantage 80 mg per 1 ml.

Superparamagnetic nanoparticle probes according to the invention can be used for labelling cells used in magnetic resonance imaging for monitoring their movement, localization, survival and differentiation especially in detection of pathologies with cell dysfunction and of tissue regeneration and also for labelling and monitoring cells administered for cell therapy purposes, in particular embryonal stem cells, fetal stem cells, stem cells of an adult human including bone marrow stem cells, olfactory glial cells, fat tissue cells, in the recipient organism by magnetic resonance.

The preparation of labelled cells proceeds by adding to the complete culture medium 5-20 μl, to advantage 10 μl, of a colloid containing 0.05-45 mg iron oxide per ml, to advantage 1-5 mg iron oxide per ml of the medium, and culturing the cells for a period of 1-7 days, to advantage for 1-3 days, at 37° C. and 5% of CO₂.

### TECHNICAL FIELD

The invention concerns superparamagnetic nanoparticle probes based on iron oxides with modified surface, method of their preparation and application.

### BACKGROUND ART

The development of medical diagnostics in recent years aims more and more at earlier diagnosis of frequently very serious diseases. A part of the new techniques is cell labeling or cell imaging by magnetic resonance. Magnetic resonance imaging (MRI) makes it possible to visualize internal organs of humans and hence is a great contribution not only in diagnostics but also in therapy and surgery. Medical diagnostics requires the use of nanometre particles. MRI makes use of the fact that magnetic nanoparticles create a magnetic field and influence the environment (Shinkai M., Functional magnetic particles for medical application, J. Biosci. Bioeng. 94, 606-613, 2002). The range of particle sizes can be divided, depending on application, into “large” (diameter>50 nm) and “small” (diameter<50 nm) particles. MR diagnostics of liver and spleen is their main application field as the particles of this size are readily and almost completely taken up by the macrophages of these organs (Kresse M., Pfefferer D., Lawaczeck R., EP 516,252 A2; Groman E. V., Josephson L., U.S. Pat. No. 4,770,183). The particles find applications also in clinical hyperthermia (Hasegawa M., Nagae H., Ito Y., Mizutani A., Hirose K., Ohgai M., Yamashita Y., Tozawa N., Yamada K., Kito K., Hokukoku S., WO 92/22586 A1; Gordon R. T., U.S. Pat. No. 4,731,239).

For labeling of cells it is of key importance to prepare monocrystalline nanoparticles of an iron oxide dispersible in water, which are also biocompatible, superparamagnetic, surface-functionalizable and which are, at the same time, completely taken up by the cells.

At present, superparamagnetic iron oxides (without magnetic memory) are the class of materials with the strongest contrast in MR (Stark D. D., Weissleder R., Elizondo G., Hahn P. F., Saini S., Todd L. E., Wittenberg J., Ferrucci J. T., Superparamagnetic iron oxide: clinical application as a contrast agent for MR imaging of the liver, Radiology 168, 297-301, 1988), hence they are in low concentrations especially suitable for tissue-specific applications. A critical size namely exists, below which the particles can have only a single magnetic domain even in zero magnetic field. The condition for superparamagnetism is KV˜kT, where KV is the anisotropy energy (K is the anisotropy constant, V is the particle volume) and k T is the thermal energy of motion (k is the Boltzmann constant, T is absolute temperature). If this condition is fulfilled, particle magnetization can be caused by thermal energy kT provided that it exceeds the potential barrier of anisotropic energy. The critical size of superparamagnetic particles of magnetite is ca. 25 nm. Superparamagnetic iron oxides make it possible to enhance the tissue contrast by increasing the relaxation rates of water. Varying the size, coating, thickness, surface chemical reactions and targeting ligands, the nanoparticle probes can be targeted on specific organs and cells or can even become in vivo molecular markers for various diseases. However, the size of crystal core of iron oxides, which causes a specific character to the materials, is problematic because it shows an essential influence on biological behavior. A small size of the particles improves their precise targeting but the efficiency of the material decreases due to interdependence of the particle size and magnetic moment. As a consequence, it is necessary to seek a compromise between good contrast effect of the material and precise targetability (Kresse M., Pfefferer D., Lawaczeck R., Wagner S., Ebert W., Elste V., Semmler W., Taupitz M. Gaida J., Herrmann A., Ebert M., Swiderski U., U.S. Pat. Appl. 2003,0185757). As a rule, the iron-containing core should be as large as possible to obtain a high imaging effect (contrast), but the overall diameter should be small.

Examples of MRI contrast agents include injectable nuclei, radionuclides, diamagnetic, paramagnetic, ferromagnetic, superparamagnetic materials, contrast materials containing iron (e.g., iron oxide, iron(III) ions, ammonium iron(III) citrate), gadolinnium agents (e.g. gadolinium diethylenetriaminepentaacetate) and manganese paramagnetic materials. Typical commercial MRI contrast agents are, e.g., Magnevist® and Resovist® (both Schering), Omniscan®, Feridex®, and Combidex® (all three Advanced Magnetics), Endorem® and Sinerem® (Guerbet), and Clariscan® (Nycomed). A number of various methods of preparation of crystals containing iron (iron oxides) with superparamagnetic properties have been described. These can be classified according to many aspects. Two basic methods of manufacture of superparamagnetic crystals are based on sintering at high temperatures and subsequent mechanical disintegration or chemical synthesis in aqueous solution. For applications in medicine, effective particles were produced by wet synthetic techniques; in contrast, sintering is described for production of iron oxides for technological (audio/video media, pigments for dyes, toners) and biotechnological applications such as magnetic separations (Schostek S., Beer A., DE 3,729,697 A1; Borelli N. F., Luderer A. A., Panzarino J. N., U.S. Pat. No. 4,323,056; Osamu I., Takeshi H., Toshihiro M., Kouji N., JP 60,260,463 A2). The wet chemical synthesis can be divided into a “two-step” synthesis, which first prepares iron oxide-containing nuclei by increasing pH, to which is subsequently added a stabilizer providing physical and other required properties (Kresse M., Pfefferer D., Lawaczeck R., Wagner S., Ebert W., Elste V., Semmler W., Taupitz M. Gaida J., Herrmann A., Ebert M., Swiderski U., U.S. Pat. Appl. 20030185757). In a “one-step” synthesis, iron oxides are prepared by precipitation of iron salts in the presence of a stabilizer, which coats the nuclei in the course of nucleation and thus hinders aggregation and sedimentation of nanocrystals. In addition to classification into “two-step” and “one-step” methods, there exists another differentiation, according to the type of the used solvent, into the methods using water (Hasegawa M., Hokukoku S., U.S. Pat. No. 4,101,435; Fuji Rebio K. K., JP 59,195,161) or organic solvents (Porath J., Mats L., EP 179,039 A2; Aoyama S., Kishimoto M., Manabe T., Interaction between polymers and magnetic particles—effect on the properties of particulate magnetic recording media, J. Mater. Chem. 2, 277-280, 1992; Norio H., Saturo O., JP 05,026,879 A2). The crude product must be always carefully purified and excess admixtures and impurities thus removed. The method of choice is then thermal sterilization. The iron oxides used at present are characterized by particle polydispersity expressed by the polydispersity index, PDI>1.3. (PDI=D_{w}/Dₙ, where Dₙ=ΣDᵢ/N a D_{w}=Σ Dᵢ⁴/Σ Dᵢ³, where N is the number of particles, Dᵢ is the diameter of an individual particle). Polydisperse particles have different physical and chemical properties, in contrast to monodisperse ones, the properties of which, including magnetic, are uniform. A drawback of classical magnetite particles also is that they change their properties in air. Their chemical instability causes uncontrolled oxidation with air oxygen, magnetic susceptibility decreases, the colloid loses stability and the nanoparticles aggregate, which is unacceptable for applications in medicine. Therefore, it is better to subject the freshly prepared magnetite particles, immediately after synthesis, to controlled oxidation to maghemite (γ-Fe₂O₃), which is stable in air and does not change its properties.

Generally, the surface of magnetic particles for imaging in medicine is covered by polymers. Almost all nanoparticles commonly used in medicine at present are iron oxides prepared in the presence of polysaccharide dextran as stabilizer (Bacic G., Niesman M. R., Bennett H. F., Magin R. L., Schwarz H. M., Modulation of water proton relaxation rates by liposomes containing paramagnetic materials, Magn. Reson. Med. 6, 445-58, 1988; Ohgushi M., Nagayama K., Wada A., Dextran-magnetite: a new relaxation agent and its application to T₂ measurements in gel systems, J. Magn. Reson. 29, 599-601, 1978; Pouliquen D., Le Jeune J. J., Perdrisot R., Ermias A., Jallet P., Iron oxide nanoparticles for use as an MRI contrast agent: pharmacokinetics and metabolism, Magn. Reson. Imaging 9, 275-283, 1991; Ferrucci J. T., Stark D. D., Iron oxide-enhanced MR imaging of the liver and spleen: review of the first years, Am. J. Roentgenol. 155, 943-950, 1990). Synthesis of such particles is usually performed according to the Molday procedure (Molday R. S., MacKenzie D., Immunospecific ferromagnetic iron-dextran agents for the labeling and magnetic separation of cells, J. Immunol. Methods 52, 353-367, 1982) requiring laborious and costly purification procedures. Dextran, however, is chemically instable, for example it depolymerizes in acid medium and various other reactions may lead to its complete destruction in alkaline medium. Moreover, cells take up the dextran-covered nanoparticles insufficiently, which does not facilitate perfect MR monitoring of cells, probably due to relatively inefficient endocytosis. In addition to dextran, the use of other polysaccharides is described such as arabinogalactan (Josephson L., Groman E. V., Menz E., Lewis J. M., Bengele H., A functionalized superparamagnetic iron oxide colloid as a receptor directed MR contrast agent, Magn. Reson. Imaging 8, 637-646, 1990), starch (Fahlvik A. K., Holtz E., Schroder U., Klaveness J., Magnetic starch microspheres, biodistribution and biotransformation. A new organ-specific contrast agent for magnetic resonance imaging, Invest. Radiol. 25, 793-797, 1990), glycosaminoglycans (Kresse M., Wagner S., Pfefferer D., Lawaczeck R., Elste V., Semmler W., Targeting of ultrasmall superparamagnetic iron oxide (USPIO) particles to tumor cells in vivo by using transferrin receptor pathways, Magn. Reson. Med. 40, 236-42, 1998) or proteins (Widder D. J., Greif W. L., Widder K. J., Edelman R. R., Brady T. J., Magnetite albumin microspheres: a new MR contrast material, Am. J. Roentgenol. 148, 399-404, 1987) such as albumin or synthetic polymers such as polymethacrylates and polysilanes. Also transfection agents are described including also poly(amino acid)s (polyalanines, poly(L-arginine)s, DNA of salmon eggs, poly(L-ornithine)s), dendrimers, polynucleotides (Frank J. A., Bulte J. W. M., Pat. WO02100269A1), polyglutamate, polyimines (Van Zijk P., Goffeney N., Duyn J. H., Bulte J. W. M., Pat. WO03049604A3).

Polymer coating considerably increases the particle size, which can affect their penetration and the rate of their metabolic removal in the body. Recently, also dispersions of bare superparamagnetic nanoparticles (polymer-uncoated) for MR imaging were described (Cheng F.-Y., Su C.-H., Yang Y.-S., Yeh C.-S., Tsai C.-Y., Wu C.-L., Wu M.-T., Shieh D.-B., Characterization of aqueous dispersions of Fe₃O₄ nanoparticles and their biomedical applications, Biomaterials 26, 729-738, 2005). They were prepared in water and stabilized with, e.g., a citrate monomer (Taupitz M., Schnorr J., Wagner S. A., Abramjuk C., Pilgrimm H., Kivelitz D., Schink T., Hansel J., Laub G., Humogen H., Hamm B., Coronary MR angiography: experimental results with a monomer-stabilized blood pool contrast medium, Radiology 222, 120-126, 2002) or tetramethylammonium hydroxide (Cheng F.-Y., Su C.-H., Yang Y.-S., Yeh C.-S., Tsai C.-Y., Wu C.-L., Wu M.-T., Shieh D.-B., Characterization of aqueous dispersions of Fe₃O₄ nanoparticles and their biomedical applications, Biomaterials 26, 729-738, 2005). The nanoparticles allegedly bring some advantages over those that require a polymer addition to be protected against aggregation. Stem cells show the ability to differentiate into any specialized cell of the organism and that is why they are in the centre of interest of human medicine, in particular regenerative medicine and cell therapy, where their utilization can be assumed. (Park H. C., Shims Y. S., Ha Y., Yoon S. H., Park S. R., Choi B. H., Park H. S., Treatment of complete spinal cord injury patients by autologous bone marrow cell transplantation and administration of granulocyte-macrophage colony stimulating factor, Tissue Eng. 11, 913-922, 2005; Akiyama Y., Radtke C., Honmou O., Kocsis J. D., Remyelination of the spinal cord following intravenous delivery of bone marrow cells, Glia 39, 229-236, 2002; Akiyama Y., Radtke C., Kocsis J. D., Remyelination of the rat spinal cord by transplantation of identified bone marrow stromal cells, J. Neurosci. 22, 6623-6630, 2002; Hofstetter C. P., Schwarz E. J., Hess D., Widenfalk J., El Manira A., Prockop J. D., Olson, L., Marrow stromal cells form guiding strands in the injured spinal cord and promote recovery, Proc. Natl. Acad. Sci. USA 96, 2199-2204, 2002; Chen J., Li Y., Katakowski M., Chen X., Wang L., Lu D., Intravenous administration of human bone marrow stromal cells induces angiogenesis in the ischemic boundary zone after stroke in rats, Circ. Res 92, 692, 2003; Chen J., Zhang Z. G., Li Y., Wang L., Xu Y. X., Gautam S. C., Intraarterial administration of marrow stromal cells in a rat model of traumatic brain injury, J. Neurosci. Res. 73, 778-786, 2003; Chopp M., Li Y., Treatment of neural injury with marrow stromal cells, Lancet Neurol. 1, 92-100, 2002; Chopp M., Zhang X. H., Li Y., Wang L., Chen J., Lu D., Spinal cord injury in rat: treatment with bone marrow stromal cell transplantation, Neuroreport 11, 3001-3005, 2000; Ramon-Cueto A., Plant G. W., Avila J., Bunge M. B., Long-distance axonal regeneration in the transected adult rat spinal cord is promoted by olfactory ensheathing glia transplants, J. Neurosci. 18, 3803-3815, 1998; Syková E., Urdziková L., Jendelová P., Burian M., Glogarová K., Hájek M., Bone marrow cells—a tool for spinal cord injury repair, Exp. Neurol. 193, 261-262, 2005).

### DISCLOSURE OF INVENTION

The subject of the invention is modified superparamagnetic nanoparticle probes based on iron oxides for diagnostic and therapeutical applications. Superparamagnetic nanoparticle probes based on iron oxides, to advantage magnetite or maghemite, with modified surface are formed by a colloid consisting of particles, the size of which ranges from 2 to 30 nm, to advantage 2-10 nm, and their polydispersity index is smaller than 1.3. Their surface is coated with mono-, di- or polysaccharides, amino acids or poly(amino acid)s or synthetic polymers based on (meth)acrylic acid and their derivatives. The saccharides are selected from the group formed by D-arabinose, D-glucose, D-galactose, D-mannose, lactose, maltose, dextrans, dextrins. The amino acid or poly(amino acid) is selected from the group formed by alanine, glycine, glutamine, asparagine, histidine, arginine, L-lysine, aspartic and glutamic acid. Polymers of derivatives of (meth)acrylic acid are selected from the group containing poly(N,N dimethylacrylamide), poly(N,N-dimethylmethacrylamide), poly(N,N-diethylacrylamide), poly(N,N-diethylmethacrylamide), poly(N-isopropylacrylamide), poly(N-isopropylmethacrylamide). The surface layer of a modification agent amounts to 0.1-30 wt. %, to advantage 10 wt. %, and the iron oxide content to 70-99.9 wt. %, to advantage 90 wt. %. The agents on the surface of particles enable their penetration into cells.

Superparamagnetic nanoparticle probes according to the invention are prepared by preprecipitation of colloidal Fe(OH)₃ by the treatment of aqueous 0.1-0.2M solution of Fe(III) salt, to advantage FeCl₃, with less than an equimolar amount of NH₄OH, at 21° C., under 2-min sonication at 350 W. To the hydroxide, 0.1-0.2M solution of a Fe(II) salt, to advantage FeCl₂, is added in the mole ratio Fe(III)/Fe(II)=2 under 2-min sonication and the mixture is poured into five- to tenfold, to advantage eightfold, molar excess of 0.5M NH₄OH. The mixture is left aging for 0-30 min, to advantage 15 min, and then the precipitate is repeatedly, to advantage 7-10 times, magnetically separated and washed with deionized water of resistivity 18 MΩ·cm⁻¹. In contrast to the present state-of the-art, 1-3 fold amount, to advantage 1.5 fold amount relative to the amount of magnetite, of 0.1 M aqueous solution of sodium citrate is added and then, dropwise, 1-3 fold amount, to advantage 1.5 fold amount relative to the amount of magnetite, of 0.7 M aqueous solution of sodium hypochlorite. The precipitate is repeatedly, to advantage 7-10 times, washed with deionized water of resistivity 18 MΩ·cm⁻¹, under the formation of colloidal maghemite to which, after dilution, is added dropwise, possibly under 5-min sonication, an aqueous solution of a modification agent in the weight ratio modification agent/iron oxide 0.1-10, to advantage 0.2 for amino acids and poly(amino acid)s and 5 for saccharides.

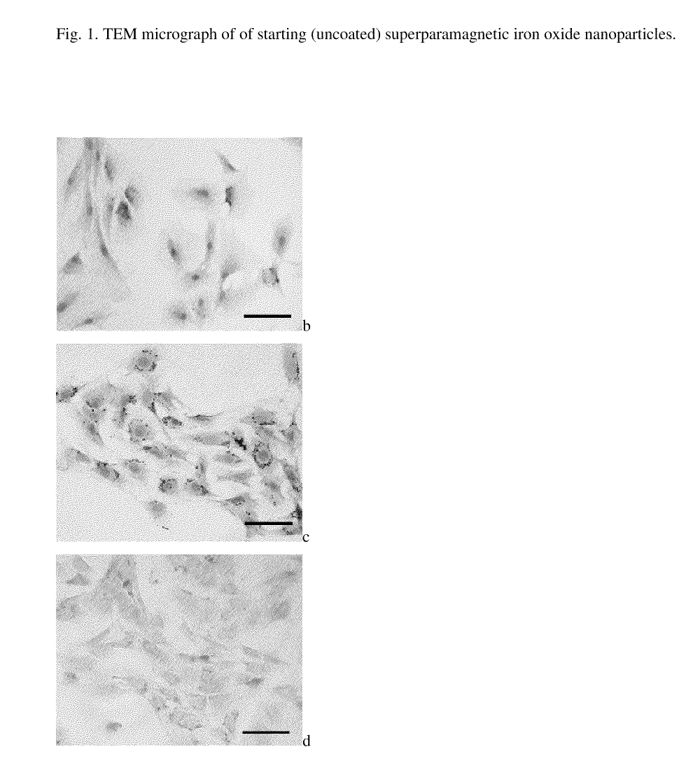

The thus prepared nanoparticles reach the size around 10 nm, according to transmission electron microscopy (TEM), with comparatively narrow size distribution characterized by PDI <1.3 (FIG. 1). The colloidal stability of the particles in water is a consequence of the presence of the charges originating from Fe(III) and citrate ions.

An essential feature of the preparation of superparamagnetic nanoparticle probes with modified surface according to the invention consists in the fact that slow addition of a solution of modification agent follows precipitation. At that, the modification agent nonspecifically adsorbs on the iron oxide surface. The interaction is a consequence of hydrogen bonds between the polar OH groups of the modification agent and hydroxylated and protonated sites on the oxide surface, or of the agent charge interacting with the citrate complexed on the iron oxide surface. The particles coated with the modification agent do not aggregate as was confirmed by TEM micrographs, according to which the size of surface-modified particles was the same as that of starting iron oxide particles.

An alternative method, which makes it possible to prepare, in contrast to the current state, very small, ca. 2 nm superparamagnetic nanoparticle probes with modified surface and a very narrow size distribution with PDI <1.1, consists in in situ precipitation of iron oxide in a solution of modification agent. The method of preparation consists in that 1 volume part of 10-60 wt. %, to advantage 50 wt. %, aqueous solution of a saccharide or polysaccharide is mixed with 1 volume part of aqueous solution of a Fe(II) and Fe(III) salt, to advantage FeCl₂ and FeCl₃, where the molar ratio Fe(III)/Fe(II)=2, at 21° C. 5-15%, to advantage 7.5%, solution of NH₄OH is added until pH 12 is attained and the mixture is heated at 60° C. for 15 min. The mixture is then sonicated at 350 W for 5 min and then washed for 24 h by dialysis in water using a membrane with molecular weight cut-off 14,000 until pH 7 is reached. The volume of solution is reduced by evaporation so that the final dry matter content is 50-100 mg, to advantage 80 mg, per 1 ml.

Nanoparticles are modified with the agents based on poly(amino acid)s such as polyalanine, polyglycine, polyglutamine, polyasparagine, polyarginine, polyhistidine or polylysine, aspartic and glutamic acids, monosaccharides (e.g. arabinose, glucose, mannose, galactose), disaccharides (e.g. lactose, maltose) and polysaccharides including starch, dextrans and dextrins, and polymers of derivatives of (meth)acrylic acid (e.g. poly(N,N-dimethylacrylamide), poly(N,N-dimethylmethacrylamide), poly(N,N-diethylacrylamide), poly(N,N-diethylmethacrylamide), poly(N-isopropylacrylamide), poly(N-isopropylmethakrylamide)).

Superparamagnetic nanoparticle probes with modified surface according to the invention are designed for labelling of living cells, in particular stem cells. The method will find broad applications in monitoring cells suitable for cell therapy (e.g., stem cells of bone marrow, olfactory glial cells, fat tissue cells). After administration of cells, their fate can be monitored in the recipient body by a noninvasive method, magnetic resonance.

It was found experimentally that the capability of targeting superparamagnetic nanoparticle probes according to the invention in cells is significantly better than with iron oxide particles according to the hitherto used methods. The uptake of poly(amino acid)-modified iron oxide nanoparticles by cells is made possible by their interaction with negatively charged cell surface and subsequent endodosomolytic absorption. The nanoparticles are in this way transferred into endosomes, fused with lysosomes under simultaneous destruction of vesicular membrane. Another mechanism of transport of nanoparticle probes into cells may consist in the mannose transporter present on the surface of many types of mammalian cells. Compared with Endorem® (0.11 mg Fe₃O₄ per ml of medium), considerably lower concentrations of iron oxide nanoparticles modified according to the invention were sufficient for complete labelling of cells. An additional advantage is that the patient organism is considerably less loaded with applied particles than it is necessary when using currently commercially available agents.

The invention provides a tool for monitoring the history and fate of cells transplanted into organism including their in vivo migration. Nanoparticle probes according to the invention are suitable for determination of diagnoses of pathologies associated with cellular dysfunction. First, the stem cells of the patient are labelled ex vivo. In cell labelling, 5-20 μl, to advantage 10 μl, of a colloid containing 0.05-45 mg iron oxide per ml, to advantage 1-5 mg iron oxide per ml of the medium, is added to complete the culture medium and the cells are cultured for 1-7 days, to advantage for 1-3 days, at 37° C. and 5% of CO₂. During the culturing, the cells fagocytize nanoparticles from the medium to cytoplasm. The thus labelled cells are introduced into the patient organism, which, when using magnetic field, makes it possible to monitor the movement, localization and survival of exogenous cells by MRI imaging and thus to reveal pathologies associated with cellular dysfunctions.

anesthesized by passive inhalation of 1.5-2% of isofloran in air. The breathing was monitored

### EXAMPLES

### Example 1

### Preparation of Starting (Uncoated) Superparamagnetic Iron Oxide Nanoparticles

12 ml of aqueous 0.2M FeCl₃ was mixed with 12 ml of aqueous 0.5M NH₄OH under sonication (Sonicator W-385; Heat Systems-Ultrasonics, Inc., Farmingdale, N.Y., USA) at laboratory temperature for 2 min. Then 6 ml of aqueous 0.2M FeCl₂ was added under sonication and the mixture was poured into 36 ml of aqueous 0.5M NH₄OH. The resulting magnetite precipitate was left aging for 15 min, magnetically separated and repeatedly (7-10 times) washed with deionized water of resistivity 18 MΩ·cm⁻¹ to remove all residual impurities (including NH₄Cl). Finally, 1.5 ml of aqueous 0.1M sodium citrate was added under sonication and magnetite was oxidized by slow addition of 1 ml of 5% aqueous solution of sodium hypochlorite. The above procedure of repeated washing afforded the starting primary colloid.

For determination of the nanoparticle size, dynamic light scattering (DLS) was used, which gave the average hydrodynamic diameter of particles amounting to 90±3 nm, suggesting a narrow size distribution. From TEM micrograph, FIG. 1, then Dₙ=6.5 nm a PDI=1.26. PDI is the polydispersity index characterizing the size distribution width, PDI=D_{w}/Dₙ where D_{w} and Dₙ are the weight- and number-average particle diameter.

### Example 2

### Treatment of Superparamagnetic Iron Oxide Nanoparticles with Poly(Amino Acid)s—“Two-Step Synthesis”

To 10 ml of the starting colloid solution containing iron oxide nanoparticles prepared according to Example 1 and diluted to the concentration 2.2 mg iron oxide/ml, 0.01-2 ml (typically 0.2 ml) of aqueous solution of a poly(amino acid) of concentration 0.5-10 mg/ml (typically 1 mg/ml) was added dropwise under stirring and the mixture was sonicated for 5 min.

The poly(amino acid) can be polyalanine, polyglycine, polyglutamine, polyasparagine, polyarginine, polyhistidine or poly(L-lysine), aspartic and glutamic acid.

### Example 3

### Treatment of Superparamagnetic Iron Oxide Nanoparticles with Saccharides—“Two-Step Synthesis”

Various volumes (0.1-5 ml) of 4 wt. % aqueous solution of a saccharide were added dropwise under stirring to 10 ml of the starting colloid solution containing iron oxide nanoparticles prepared according to Example 1, diluted to the concentration 2.2 mg iron oxide/ml and the mixture was sonicated for 5 min. The particles were repeatedly washed.

The saccharide can be D-arabinose, D-glucose, D-galactose, D-mannose, lactose, maltose, dextrans, dextrins.

### Example 4

### Treatment of Superparamagnetic Iron Oxide Nanoparticles with (Meth)Acrylic Acid Derivatives—“Two-Step Synthesis”

To an 0.003-0.07 wt. % (typically 0.03 wt. %) solution of 4,4′-azobis(4-cyanopentanoic acid) was added a corresponding amount of the colloid containing 0.1-2 g (typically 0.5 g) of particles prepared according to Example 1 so that the total volume of the mixture was 30 ml. To the solution was added 0.1-2 (typically 1) g of a (meth)acrylic acid derivative, the solution was bubbled with nitrogen for 10 min and heated at 70° C. for 8 h under stirring (400 rpm). The resulting product was repeatedly (3-5 times) magnetically separated or centrifuged (14 000 rpm), washed with water or isotonic 0.15M sodium chloride and sonicated until the formation of a colloidal solution.

The (meth)acrylic acid derivative can be poly(N,N-dimethylacrylamide), poly(N,N-dimethylmethacrylamide), poly(N,N-diethylacrylamide), poly(N,N-diethylmethacrylamide), poly(N-isopropylacrylamide), poly(N-isopropylmethacrylamide).

### Example 5

### In Situ Precipitation of Superparamagnetic Iron Oxide Nanoparticles in a Saccharide Solution

10 ml of 50 wt. % aqueous solution of a saccharide was mixed under stirring with 10 ml of an aqueous solution containing 1.51 g of FeCl₃.6H₂O and 0.64 g of FeCl₂.4H₂O. 15 ml of a 7.5% aqueous NH₄OH was slowly added until pH 12 was attained and the mixture was heated at 60° C. for 15 min. Big aggregates were broken by sonication (Sonicator W-385, Heat Systems-Ultrasonics Inc., Farmingdale, N.Y., USA, 350 W) for 5 min. To remove water-soluble salts and excess saccharide, the particles were washed by water dialysis on a Visking membrane (molecular weight cut-off 14,000, Carl Roth GmbH, Germany) for 24 h at room temperature (water exchanged five times, each time 2 l) until pH 7 was reached. The volume was reduced by evaporation: dry matter 80 mg iron oxide per ml of colloid.

The saccharide can be D-arabinose, D-glucose, D-galactose, D-mannose, lactose, maltose, dextran, dextrins.

### Example 6

### Optical Microscopy of Labelled Cells

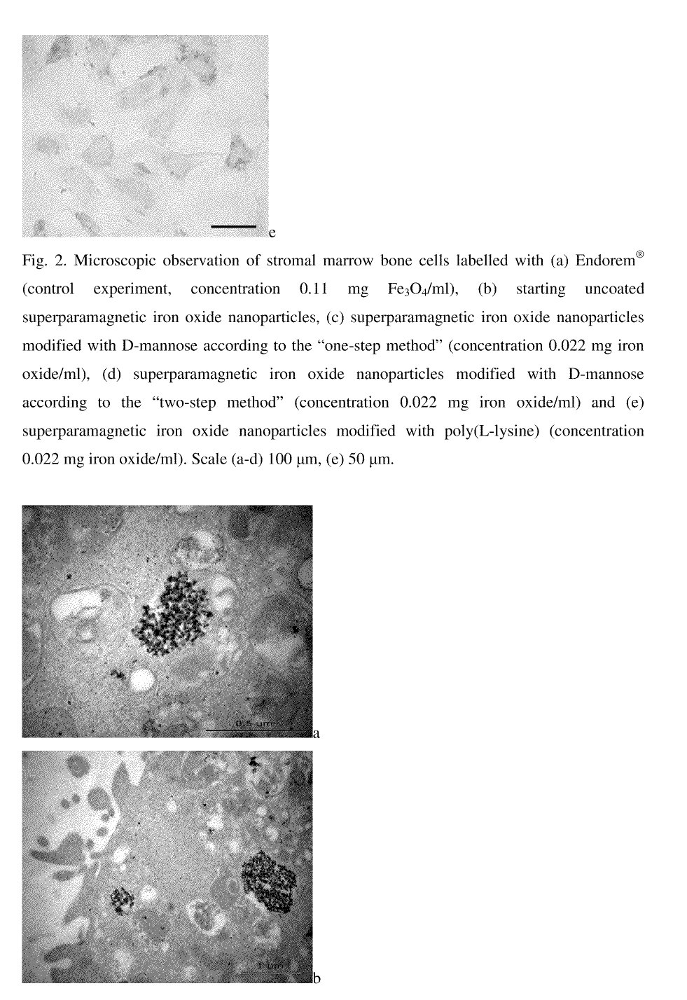

Stromal cells of bone marrow (MSC) of rat labelled by both starting uncoated and surface-modified superparamagnetic iron oxide nanoparticles were observed in optical microscope. The cells labelled with Endorem® (0.11 mg Fe₃O₄/ml) served as control (FIG. 2 a). A drawback of Endorem® was its tendency to adhere to the cell surface; moreover, it sticked also to the bottom of vessel.

The cells in contact with starting (uncoated) nanoparticles prepared according to Example 1 proliferated and approximately one of every ten cells endocytized iron oxide nanoparticles of iron oxide (FIG. 2 b).

The cells in contact with starting (uncoated) nanoparticles modified with D-mannose by the “one-step method” (prepared by in-situ precipitation in concentrated solution of D-mannose according to Example 4) proliferated well already at concentration 0.02 mg iron oxide/ml, without forming aggregates of particles adhering to cell surface (FIG. 2 c).

From observation of the cells in contact with superparamagnetic nanoparticles modified with D-mannose by the “two-step method” (after the synthesis) according to Example 3, the optimum concentration of D-mannose added to the colloid was assessed amounting to 12.8 mg D-mannose per ml of the colloid, which ensures labelling of ca. 50% of cell population (FIG. 2 d).

Maximum labelling of cells (almost 100%) was achieved with poly(L-lysine)-modified nanoparticles (0.02 mg poly(L-lysine) per ml colloid (FIG. 2 e)).

### Example 7

### Transmission Electron Microscopy of Cells Labelled with Superparamagnetic Iron Oxide Nanoparticles

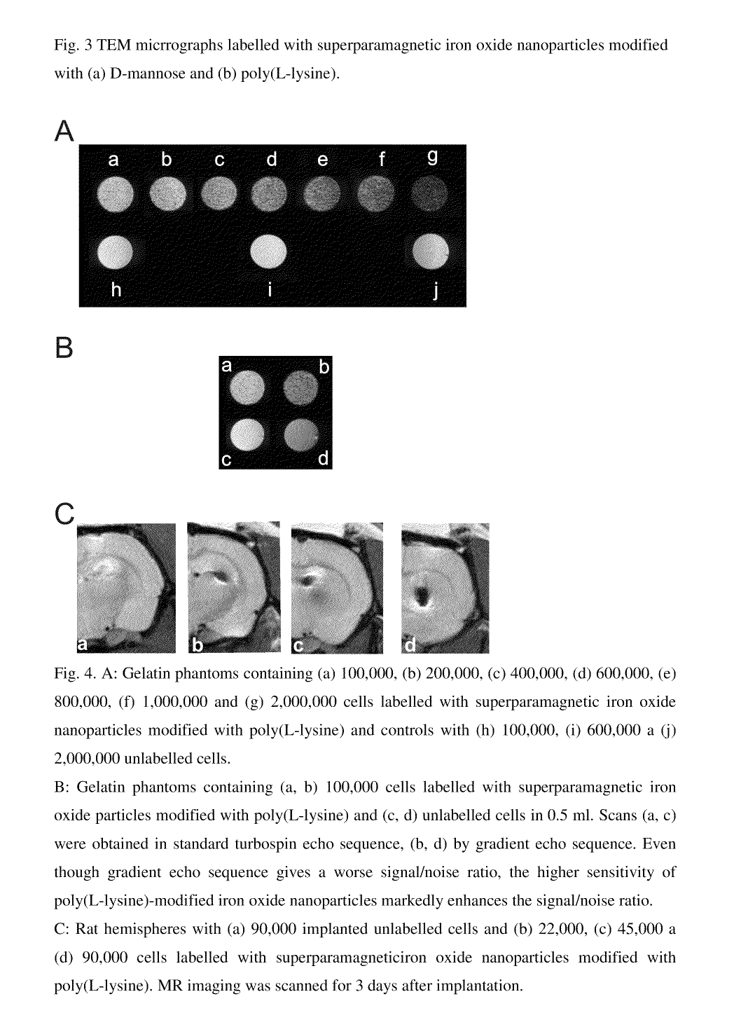

Transmission electron micrograph of MSC cells labelled with superparamagnetic nanoparticles of iron oxide modified with D-mannose according to Example 3 and with poly(L-lysine) (PLL) according to Example 2 is shown in FIG. 3. Numerous aggregates of both types of superparamagnetic nanoparticles inside cells labelled with nanoparticles modified with both D-mannose and poly(L-lysine) are visible. The nanoparticle aggregates were evenly distributed in cell cytoplasm; their accumulation on cell membranes was not perceptible.

### Example 8

### Quantitative Determination of Cells Labelled with Superparamagnetic Iron Oxide Nanoparticles

Superparamagnetic iron oxide nanoparticles modified with both poly(L-lysine) according to Example 2 and with D-mannose according to Example 3 were successfully endocytized by MSC cells (as follows from FIGS. 2 and 3). MSC cells were cultivated in duplicate on uncoated six-well culture plates at the density 10⁵ cells per mm². Endorem® and the nanoparticles modified with poly(L-lysine) or D-mannose were added to culture medium (10 μl/ml) and the cells incubated for 72 h. After washing out excess contrast substance with the culture medium, the cells were fixed with 4% solution of paraformaldehyde in 0.1 M phosphate buffer (PBS) and tested for iron under the formation of iron(III) ferrocyanide (Prussian Blue). The number of labelled and unlabelled cells was determined in an inverted light microscope (Axiovert 200, Zeiss) by counting randomly selected five fields per well and two wells per each run (Table 1). The cells in each image were manually labeled as Prussian Blue-positive or -negative; the number of labeled cells was then counted using the image analysis toolbox in program Matlab 6.1 (The MathWorks, Natick, Mass., USA). The best labelling of cells was obtained with nanoparticles containing 0.02 mg poly(L-lysine) per ml of colloid.

TABLE 1
Percentage of stromal cells of bone marrow (MSC) labelled
in vitro with superparamagnetic nanoparticles

| | Uncoated | PLL-modifid iron oxide | D-Mannose-modified | |
|---|---|---|---|---|
| | iron oxide | (0.02 mg PLL/ml) | iron oxide | Endorem ® |
| MSC (rat) | 27.9 | 92.2 | 50.8 | 60.0 |
| MSC (human) | not tested | 87.5 | not tested | 65.2 |

### Example 9

### Relativity of Cells Labelled with Superparamagnetic Iron Oxide Nanoparticles Modified with poly(L-lysine)

To further verify the presence of poly(L-lysine)-modified superparamagnetic iron oxide nanoparticles prepared according to Example 2 in bone marrow cells (MSCs), samples with suspension of Endorem® and poly(L-lysine)-modified superparamagnetic nanoparticles in a 4% gelatin solution and samples with suspensions of Endorem®-labelled cells and poly(L-lysine)-modified superparamagnetic nanoparticles with various amounts of cells in gelatin solution were prepared. Subsequently, relaxation times of samples were measured and their MR images were obtained.

For determination of relaxation times T₁ a T₂, a relaxometer Bruker Minispec 0.5 T was used. The values were recalculated to proton relaxivities R₁=1/T₁, R₂=1/T₂ and related to real concentrations r₁=R_{11c} (s⁻¹/mmol), r₂=R₂/c (s⁻¹/mmol), or they are related to the number of cells in 1 ml, where R₂ and R₁ are corrected for gelatin. The relativity values are given in Tables 2 and 3. From Table 3 follows that the r₂ value of poly(L-lysine)-modified superparamagnetic iron oxide nanoparticles according to Example 2 is considerably higher than with Endorem®.

TABLE 2
r₁ values of poly(L-lysine)-modified superparamagnetic
iron oxide nanoparticles (PLL) and Endorem ®

| | Relaxivity r₁ of suspension | Relaxivity r₁ of suspension |
|---|---|---|
| | of contrast agent in gelatin | of labelled cell in gelatin |
| | (s⁻¹/mmol Fe) | (s⁻¹/10^{⁶} cells per ml) |
| PLL-modified | 17.4 | 0.32 |
| iron oxide | | |
| Endorem ® | 19.6 | 0.18 |

TABLE 3
r₂ values of poly(L-lysine)-modified superparamagnetic
iron oxide nanoparticles (PLL) and Endorem ®

| | Relaxivity r₂ of contrast | Relaxivity r₂ of labelled cell |
|---|---|---|
| | material suspension in | suspension in gelatin |
| | gelatin (l⁻¹/mmol Fe) | (s⁻¹/10^{⁶} cells per ml) |
| PLL-modified | 213 | 4.29 |
| iron oxide | | |
| Endorem ® | 126 | 1.24 |

The average iron content determined spectrophotometrically after mineralization amounted to 35.9 pg Fe per cell in poly(L-lysine)-modified superparamagnetic iron oxide nanoparticles and 14.6 pg Fe per cell in Endorem®-labelled cells

### Example 10

### In Vitro MR Imaging of Cells Labelled with Superparamagnetic Nanoparticle Probes

Imaging of labelled cells in vitro is advantageous for proof of MRI sensitivity and, at the same time, for imitating the course of the signal in brain tissue. Rat MSC cells were labelled with poly(L-lysine)-modified superparamagnetic iron oxide nanoparticles according to Example 2 and a cell suspension in a 4% gelatin solution of concentration 4,000, 2,000, 1,600, 1,200, 800, 400 and 200 cells per μl was prepared. The unlabelled MSC rat cells were suspended in a 4% gelatin solution of concentration 4,000, 1,200 and 200 cells per μl.

The cell samples were subsequently imaged with a 4.7 T Bruker spectrometer using standard turbospin sequence (sequence parameters: repetition time TR=2 000 ms, effective echo-time TE=42.5 ms, turbo factor=4, number of acquisitions AC=16, image field FOV=64×64 mm, matrix MTX=512×512, layer thickness 0.75 mm; the set geometry affords a comparable size of voxel as in in vivo measurement) and the gradient echo sequence (TR=180 ms, TE=12 ms, the same geometry of imaging).

When using both sequences, the cells labelled with poly(L-lysine)- or D-mannose-modified superparamagnetic iron oxide nanoparticles modified with poly(L-lysine) (FIG. 4 A, B) or D-mannose afford an excellent contrast compared with unlabelled cells. A visible contrast in MR image was observed also in a sample, each image voxel of which contained mere 2.3 cells on average. A similar series of experiments were given in the preceding work (Jendelová P., Herynek V., DeCroos J., Glogarová K., Andersson B., Hájek M., Syková E., Imaging the fate of implanted bone marrow stromal cells labeled with superparamagnetic nanoparticles, Magn. Reson. Med. 50, 767-776, 2003), where MR imaging of gelatin phantoms showed a hypointensive signal at concentrations above 625 cells per μl.

### Example 11

### In Vivo MR Imaging of Cells Labelled with Superparamagnetic Nanoparticle Probes

Wistar rats were in the course of measurement. The rats were monitored for 3 days after transplantation in a Bruker 4.7 T spectrometer equipped with a surface coil of domestic production. Simple sagital, coronal and transverse scans were obtained by a fast gradient echo sequence for localization of subsequent T₂- and T₂*-weighted images measured by standard turbospin sequence (TR=2 000 ms, TE=42.5 ms, turbo factor=4, AC=16, FOV=30×30 mm, matrix MTX 256×256, layer thickness 0.75 mm) and gradient echo sequence (TR=180 ms, TE=12 ms, the same geometry of imaging). FIG. 4 C proves that cells labelled with poly(L-lysine)-modified superparamagnetic iron oxide nanoparticles according to Example 2 were clearly discernible also in vivo. Unlabelled cell implants were visible in MR images as a tissue inhomogeneity without a hypotensive signal (FIG. 4 C).

FIG. 1. TEM micrograph of starting (uncoated) superparamagnetic iron oxide nanoparticles.

FIG. 2. Microscopic observation of stromal marrow bone cells labelled with (a) Endorem® (control experiment, concentration 0.11 mg Fe₃O₄/ml), (b) starting uncoated superparamagnetic iron oxide nanoparticles, (c) superparamagnetic iron oxide nanoparticles modified with D-mannose according to the “one-step method” (concentration 0.022 mg iron oxide/ml), (d) superparamagnetic iron oxide nanoparticles modified with D-mannose according to the “two-step method” (concentration 0.022 mg iron oxide/ml) and (e) superparamagnetic iron oxide nanoparticles modified with poly(L-lysine) (concentration 0.022 mg iron oxide/ml). Scale (a-d) 100 μm, (e) 50 μm.

FIG. 3 TEM micrrographs labelled with superparamagnetic iron oxide nanoparticles modified with (a) D-mannose and (b) poly(L-lysine).

FIG. 4. A: Gelatin phantoms containing (a) 100,000, (b) 200,000, (c) 400,000, (d) 600,000, (e) 800,000, (f) 1,000,000 and (g) 2,000,000 cells labelled with superparamagnetic iron oxide nanoparticles modified with poly(L-lysine) and controls with (h) 100,000, (i) 600,000 a 2,000,000 unlabelled cells.

B: Gelatin phantoms containing (a, b) 100,000 cells labelled with superparamagnetic iron oxide particles modified with poly(L-lysine) and (c, d) unlabelled cells in 0.5 ml. Scans (a, c) were obtained in standard turbospin echo sequence, (b, d) by gradient echo sequence. Even though gradient echo sequence gives a worse signal/noise ratio, the higher sensitivity of poly(L-lysine)-modified iron oxide nanoparticles markedly enhances the signal/noise ratio. C: Rat hemispheres with (a) 90,000 implanted unlabelled cells and (b) 22,000, (c) 45,000 a (d) 90,000 cells labelled with superparamagneticiron oxide nanoparticles modified with poly(L-lysine). MR imaging was scanned for 3 days after implantation.

### INDUSTRIAL APPLICABILITY

The invention can be exploited in human and veterinary medicine, biology and microbiology.

1. Superparamagnetic nanoparticle probes based on iron oxides, to advantage magnetite or maghemite, with modified surface, characterized in that they are coated with mono-, di- or polysaccharides from the group including D-arabinose, D-glucose, D-galactose, D-mannose, lactose, maltose, dextrans and dextrins or amino acids or poly(amino acid)s from the group including alanine, glycine, glutamine, asparagine, histidine, arginine, L-lysine, aspartic and glutamic acid or polymers of (meth)acrylic acid derivatives from the group containing poly(N,N-dimethylacrylamide), poly(N,N-dimethylmethacrylamide), poly(N,N-diethylacrylamide), poly(N,N-diethylmethacrylamide), poly(N-isopropylacrylamide), poly(N-isopropylmethacrylamide) and form a colloid consisting of particles with narrow size distribution with polydispersity index lower than 1.3, the average size of which ranges from 0.5 to 30 nm, to advantage 1-10 nm, iron oxide content amounts to 70-99.9 wt. %, to advantage 90 wt. %, the modification agent content makes 0.1-30 wt. %, to advantage 10 wt. %.

2. Superparamagnetic nanoparticle probes according to claim 1, characterized in that their size is smaller than 2 nm and polydispersity index lower than 1.1.

3. Method of preparation of superparamagnetic nanoparticle probes characterized in that colloidal Fe(OH)₃ is preprecipitated by the treatment of aqueous 0.1-0.2 M solution of Fe(III) salt, to advantage FeCl₃, under sonication, with less than an equimolar amount of NH₄OH, at 21° C., to which 0.1-0.2 M solution of a Fe(II) salt, to advantage FeCl₂, is added in the mole ratio Fe(III)/Fe(II)=2 and the mixture is poured into five- to tenfold, to advantage eightfold, molar excess of 0.5M NH₄OH, the mixture is left aging for 0-30 min, to advantage for 15 min, then the precipitate is repeatedly, to advantage 7-10 times, magnetically separated and washed with deionized water of resistivity 18 MΩ·cm⁻¹, then a 1-3 fold amount, to advantage 1.5 fold amount relative to the amount of magnetite, of 0.1 M aqueous solution of sodium citrate is added under sonication and then, dropwise, 1-3 fold amount, to advantage 1.5 fold amount relative to the amount of magnetite, of 0.7 M aqueous solution of sodium hypochlorite. The precipitate is repeatedly, to advantage 7-10 times, washed with deionized water of resistivity 18 MΩ·cm⁻¹, under the formation of colloidal maghemite to which, after dilution, is added dropwise, possibly under 5-min sonication, an aqueous solution of a modification agent in the weight ratio modification agent/iron oxide 0.1-10, to advantage 0.2 for amino acids and poly(amino acid)s and 5 for saccharides.

4. Method of preparation of superparamagnetic nanoparticle probes characterized in that 1 volume part of 10-60 wt. %, to advantage 50 wt. %, aqueous solution of a saccharide or polysaccharide, such as D-arabinose, D-glucose, D-galactose, D-mannose, lactose, maltose, dextran and dextrins, is mixed with 1 volume part of aqueous solution of a Fe(II) and Fe(III) salt, to advantage FeCl₂ and FeCl₃, where the molar ratio Fe(III)/Fe(II)=2, at 21° C. 5-15%, to advantage 7.5%, solution of NH₄OH is added until pH 12 is attained and the mixture is heated at 60° C. for 15 min. The mixture is then sonicated at 350 W for 5 min and then washed by dialysis in water using a membrane with molecular weight cut-off 14,000 for 24 h until pH 7 is reached. The volume of solution is reduced by evaporation so that the dry matter content is 50-100 mg, to advantage 80 mg, per 1 ml.

5. The application of superparamagnetic nanoparticle probes according to claim 1 to labelling cells used in magnetic resonance imaging for monitoring their movement, localization, survival and differentiation especially in detection of pathologies with cell dysfunction and of tissue regeneration.

6. The application of superparamagnetic nanoparticle probes according to claim 1 to labelling and monitoring cells administered for cell therapy purposes, in particular embryonal stem cells, fetal stem cells, stem cells of an adult human including bone marrow stem cells, olfactory glial cells, fat tissue cells in the recipient organism by magnetic resonance.

7. The application of superparamagnetic nanoparticle probes according to claim 1 to labelling of cells, especially adherent, for monitoring the fate of transplanted cells in organism by magnetic resonance imaging characterized in that 5-20 μl, to advantage 10 μl, of a colloid containing 0.05-45 mg iron oxide per ml, to advantage 1-5 mg iron oxide per ml of the medium, is added to the complete culture medium and the cells are cultured for 1-7 days, to advantage for 1-3 days, at 37° C. and 5% of CO₂.
